(19) United States
(12) Patent Application Publication
(10) Pub. No.: US 2026/0018391 A1
(43) Pub. Date: Jan. 15, 2026

(54) EDGE RING VOLTAGE AND PHASE MEASUREMENT AND CONTROL FOR SUBSTRATE PROCESSING SYSTEMS

(71) Applicant: LAM RESEARCH CORPORATION, Fremont, CA (US)

(72) Inventors: Dong Woo PAENG, Albany, CA (US); Ryan BISE, Campbell, CA (US); John HOLLAND, San Jose, CA (US); Paul ROBERTSON, Fremont, CA (US)

(21) Appl. No.: 18/992,503

(22) PCT Filed: Jul. 10, 2023
(86) PCT No.: PCT/US2023/027213

§ 371 Date: Jan. 8, 2025

Related U.S. Application Data
(60) Provisional application No. 63/389,520, filed on Jul. 15, 2022.

(51) Int. Cl. H01J 37/32; G01R 25/00; H01L 21/67

(52) U.S. Cl. CPC H01J 37/32697; G01R 25/00; H01J 37/32541; H01J 2237/24564; H01L 21/67069

(57) ABSTRACT

A voltage control system is disclosed and includes: an edge ring configured to be disposed on a substrate support and surround an outer periphery of a substrate; a tunable edge sheath (TES) ring; a generator; and a controller. The TES ring includes: a TES power electrode capacitively coupled to the edge ring and configured to receive a first radio frequency (RF) voltage signal; and a TES probe electrically coupled to the edge ring and configured to detect a second RF voltage signal at the edge ring. The controller is configured to, based on the second RF voltage signal, control the generator to adjust the first RF voltage signal.

### CROSS-REFERENCE TO RELATED APPLICATIONS

This application claims the benefit of U.S. Provisional Application No. 63/389,520, filed on Jul. 15, 2022. The entire disclosure of the above application is incorporated herein by reference.

### FIELD

The present disclosure relates to control systems for controlling radio frequency (RF) voltages in substrate processing systems and more particularly to edge ring voltage control systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing system typically includes multiple processing chambers (also called process modules) to perform deposition, etch, and other treatments of substrates such as semiconductor wafers. Examples of processes that may be performed on a substrate include plasma enhanced chemical vapor deposition (PECVD), chemically enhanced plasma vapor deposition (CEPVD), sputtering physical vapor deposition (PVD), atomic layer deposition (ALD), and plasma enhanced ALD (PEALD). Additional examples of processes that may be performed on a substrate include etching (e.g., chemical etching, plasma etching, reactive ion etching, etc.) and cleaning processes.

During processing, a substrate is arranged on a substrate support, such as a pedestal or an electrostatic chuck (ESC), in a processing chamber of the substrate processing system. A computer-controlled robot typically transfers substrates from one processing chamber to another in a sequence in which the substrates are to be processed. During deposition, gas mixtures including one or more precursors are introduced into the processing chamber, and plasma is struck to activate chemical reactions. During etching, gas mixtures including etch gases are introduced into the processing chamber, and plasma is struck to activate chemical reactions. The processing chambers are periodically cleaned by supplying a cleaning gas into the processing chamber and striking plasma.

### SUMMARY

A voltage control system is disclosed and includes: an edge ring configured to be disposed on a substrate support and surround an outer periphery of a substrate; a tunable edge sheath (TES) ring; a generator; and a controller. The TES ring includes: a TES power electrode capacitively coupled to the edge ring and configured to receive a first radio frequency (RF) voltage signal; and a TES probe electrically coupled to the edge ring and configured to detect a second RF voltage signal at the edge ring. The controller is configured to, based on the second RF voltage signal, control the generator to adjust the first RF voltage signal.

In other features, the TES power electrode and the TES probe are at least partially embedded within the TES ring. In other features, the TES power electrode and the TES probe are fully embedded within the TES ring.

In other features, the TES probe directly contacts the edge ring for direct detection of the second RF voltage signal. In other features, the TES probe is capacitively coupled to the edge ring for indirect detection of the second RF voltage signal.

In other features, the edge ring is disposed on and is in contact with the TES ring. In other features, the TES ring has a bottom surface. A top surface of the TES probe faces and extends parallel to the bottom surface of the TES ring.

In other features, at least one of the TES power electrode and the TES probe are ring-shaped. In other features, the TES power electrode is ring-shaped. The TES probe is disposed radially inward or radially outward of the TES power electrode.

In other features, the TES probe extends vertically and is disposed radially outward of the TES power electrode. In other features, the TES power electrode is ring-shaped and includes an opening. A portion of the TES probe extends through the opening.

In other features, a gap exists between the TES power electrode and the TES probe. In other features, the TES power electrode is ring-shaped. The TES probe is ring-shaped.

In other features, a half cross-sectional width of the TES probe is greater than a half cross-sectional width of the TES probe. In other features, a half cross-sectional width of the TES probe is equal to a half cross-sectional width of the TES probe. In other features, a half cross-sectional width of the TES probe is less than a half cross-sectional width of the TES probe.

In other features, the TES probe is vertically offset from the TES power electrode. In other features, the TES probe is disposed closer to the edge ring than the TES power electrode.

In other features, the TES ring is formed of a dielectric material. The TES power electrode and TES probe are embedded in the TES ring such that a portion of the dielectric material is disposed between i) the TES power electrode and the TES probe, and ii) the edge ring.

In other features, the voltage control system further includes a sensor configured to detect magnitude and phase of a third RF voltage signal supplied to a RF electrode of the substrate support. The controller is configured to, based on a magnitude and phase of the second RF voltage signal and the magnitude and phase of the third RF voltage signal, adjust the first RF voltage signal.

In other features, the controller is configured to adjust the first RF voltage signal to match the second RF voltage signal to the third RF voltage signal in at least one of magnitude and phase. In other features, the controller is configured to determine whether the second RF voltage signal is unstable and compensate for the instability of the second RF voltage signal by adjusting the first RF voltage signal.

In other features, the controller is configured to: based on the second RF voltage signal, determine a state of health of at least one of the edge ring or the TES ring; and based on the state of health, determine whether to at least one of permit continued processing of the substrate or whether to perform a countermeasure.

In other features, a substrate processing system is disclosed and includes: the voltage control system; the substrate support including a RF electrode; and a sensor configured to detect a third RF voltage signal supplied to the RF electrode. The controller is configured to, based on both the second RF voltage signal and the third RF voltage signal, adjust the first RF voltage signal.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of a substrate processing system including an edge ring voltage control system in accordance with the present disclosure;

FIG. 2 is an example of an edge ring voltage control system in accordance with the present disclosure;

FIG. 3 is a side cross-sectional view of a substrate support including an edge ring and an example of a tunable edge sheath (TES) ring having a direct measurement TES probe in accordance with the present disclosure;

FIG. 4 is a side cross-sectional view of a substrate support including an edge ring and an example of a TES ring having an indirect measurement TES probe in accordance with the present disclosure;

FIG. 5 is a side cross-sectional view of a substrate support including an edge ring and an example of a TES ring having an indirect measurement TES probe with a larger surface area facing the edge ring than does a TES power electrode in accordance with the present disclosure;

FIG. 6 is a cross-sectional top view of an example TES ring including a ring-shaped TES power electrode with an opening for a direct measurement TES probe in accordance with the present disclosure;

FIG. 7 is a cross-sectional top view of an example TES ring including a ring-shaped TES power electrode and a ring-shaped indirect measurement TES probe in accordance with the present disclosure; and

FIGS. 8A-8B illustrates an edge ring voltage and phase measurement and control method including diagnostic operations in accordance with the present disclosure.

In the drawings, reference numbers may be reused to identify similar and/or identical elements.

### DETAILED DESCRIPTION

In processing chambers performing plasma etch processes on semiconductor substrates (typically under vacuum), an edge ring (also referred to as a top ring) is arranged around and adjacent to an outer periphery of a substrate support. The edge ring may be supplied an RF voltage via TES hardware to adjust shape of plasma near an edge of a substrate supported by the substrate support. The TES hardware can include a TES ring having a TES power electrode that receives the RF voltage. The TES power electrode is embedded in the TES ring and is capacitively coupled to the edge ring. The RF voltage of the TES power electrode can be set to improve etch uniformity of the substrate.

A controller may detect an RF voltage output by an RF generator and/or provided to a TES power electrode and adjust the RF voltage to provide a target etch or deposition profile across a substrate. Control of the RF voltage can be imprecise because the magnitude and phase of the RF voltage generated by the RF generator is often different than the actual magnitude and phase of an RF voltage at an edge ring. This is because of i) capacitive coupling between a corresponding substrate support and the edge ring, ii) capacitive coupling between a TES power electrode and the edge ring, iii) impedance change in plasma over the substrate support and the edge ring, and iv) parasitic coupling of substrate system components. Impedance of plasma changes with different applied RF voltages, which results in differences in the magnitude and phase of the RF voltage out of the RF generator and the actual RF voltage at the edge ring. Differences in magnitude and phase can also occur due to different system configurations including for example different disposed heights of the edge ring relative to the substrate support and/or relative to a substrate supported on the substrate support. Thus, there is not a direct correlation between the magnitude and phase of the generated RF voltage and the magnitude and phase of the RF voltage at the edge ring.

Differences between the magnitude and phase of the RF voltage at an edge ring and magnitude and phase of RF voltage supplied to a substrate support can result in etch rate non-uniformity and a distorted profile across a substrate. Tuning of etch rate uniformity across a surface of a substrate, especially near an outer peripheral edge of the substrate, is challenging.

The examples set forth herein include RF voltage detection and control systems configured to directly or indirectly detect RF voltages and phases of edge rings and control magnitudes and phases of the RF voltages at the edge rings. The RF voltage detection and control systems include TES rings with TES power electrodes and TES probes. The TES probes may be in direct contact with, adjacent to or indirectly coupled to the edge rings. The TES probes may directly detect RF voltages at one or more contact points. Indirect arrangements include TES probes being capacitively coupled to the edge rings. The TES probes may be ring-shaped and have large surface areas for indirectly detecting RF voltages of edge rings via capacitive coupling. The TES power electrodes and the TES probes may be embedded in the TES rings. In one embodiment, a TES probe extends through the corresponding TES ring to be in direct contact with an edge ring. In other embodiments, TES probes are embedded in TES rings and are capacitively coupled to corresponding edge rings. These and other examples are further described below.

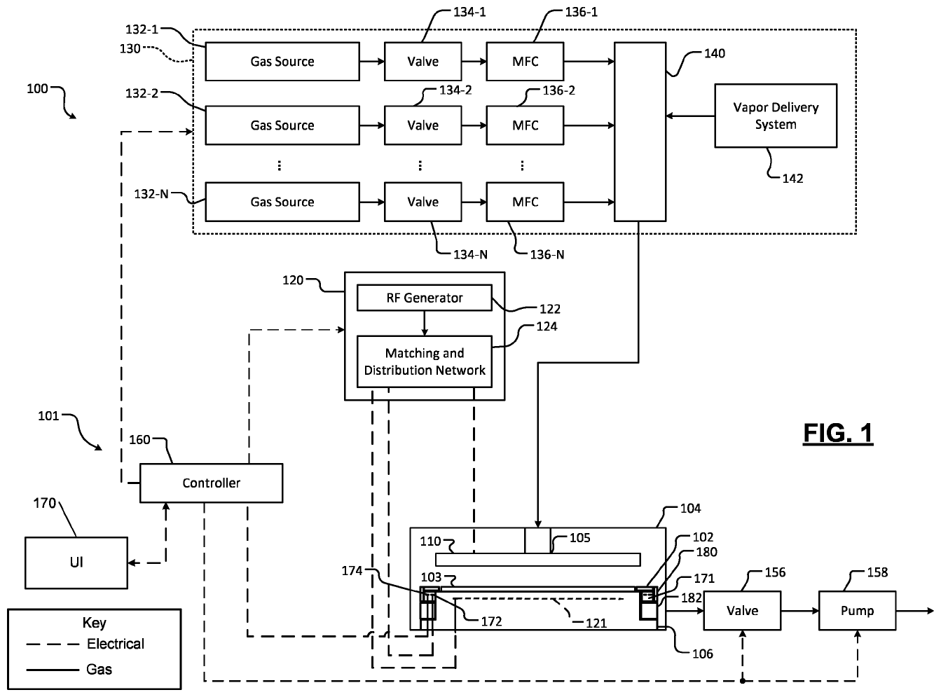

FIG. 1 shows a substrate processing system 100 including an edge ring voltage control system 101 for measuring and controlling RF voltages and phases at an edge ring 102 and thus at an edge of a substrate 103. The substrate processing system 100 includes a processing chamber 104, which may be configured to generate capacitively coupled plasma. The processing chamber 104 encloses components of the substrate processing system 100 and contains RF plasma (if used). The processing chamber 104 includes an upper electrode 105 and a substrate support 106 (e.g., an electrostatic chuck (ESC)) or other type of substrate support. During operation, the substrate 103 is arranged on the substrate support 106.

As an example, the upper electrode 105 may include a gas distribution device 110 such as a showerhead that introduces and distributes process gases. The gas distribution device 110 may include a stem portion including one end connected to a top surface of the processing chamber 104. A base portion of the showerhead is generally cylindrical and extends radially outwardly from an opposite end of the stem portion at a location that is spaced from the top surface of the processing chamber 104. A substrate-facing surface or faceplate of the base portion of the showerhead includes multiple holes through which vaporized precursor, process gas, cleaning gas or purge gas flows. Alternately, the upper electrode 105 may include a conducting plate, and the gases may be introduced in another manner.

If plasma is used, an RF generating system (or an RF source) 120 generates and outputs an RF voltage to one of the upper electrode 105 and a lower electrode 121. The other one of the upper electrode 105 and the lower electrode 121 may be DC grounded, AC grounded, or floating. For example, the RF generating system 120 may include an RF generator 122 that generates RF power that is fed by a matching and distribution network 124 to the upper electrode 105 or the lower electrode 121. In other examples, while not shown, the plasma may be generated inductively or remotely and then supplied to the processing chamber 104. The lower electrode 121 may be embedded in the substrate support 106.

A gas delivery system 130 includes one or more gas sources 132-1, 132-2, . . . , and 132-N (collectively gas sources 132), where N is an integer greater than zero. The gas sources 132 are connected by valves 134-1, 134-2, . . . , and 134-N (collectively valves 134) and mass flow controllers 136-1, 136-2, . . . , and 136-N (collectively mass flow controllers 136) to a manifold 140. A vapor delivery system 142 supplies vaporized precursor to the manifold 140 or another manifold (not shown) that is connected to the processing chamber 104. An output of the manifold 140 is fed to the processing chamber 104. The gas sources 132 may supply process gases, cleaning gases, and/or purge gases. A valve 156 and pump 158 may be used to evacuate reactants from the processing chamber 104.

A system controller 160 controls the components of the substrate processing system 100. A user interface (UI) 170 interfaces with the substrate processing system 100 via the system controller 160.

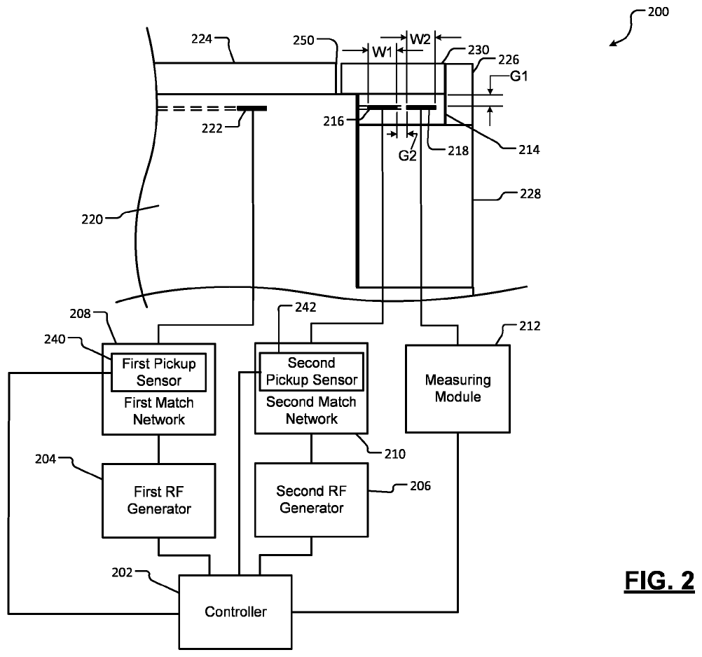

The edge ring voltage control system 101 includes the system controller 160, the RF generating system 120, a TES ring 171 having a TES power electrode 172, and a TES probe 174. The edge ring voltage control system 101 may also include the lower electrode 121. The system controller 160 detects magnitude and phase of RF voltage signals at the edge ring via the TES probe 174 and, based on these measurements, controls the RF generating system 120 to adjust voltages and phases at the edge ring 102 and a TES of plasma. This control and other example arrangements are further described below with respect to FIGS. 2-8.

The substrate support 106 may further include a cover ring 180 and an insulator ring 182. The cover ring 180 may be included to protect outer edges of the rings 102 and 171. The substrate support 106 and the rings 171, 180, 182 may be formed of ceramic and/or other dielectric material. The cover ring 180 may be formed of quartz ceramic. The substrate support 106 and the rings 171, 182 may be formed of alumina ceramic. The edge ring 102 may be formed of silicon carbide, stainless steel, copper, aluminum and/or other suitable conductive material. The lower electrode 121, TES power electrode 172, and the TES probe 174 may be formed of copper, nickel and/or other suitable conductive material.

FIG. 2 shows an edge ring voltage control system 200 that may be implemented in the substrate processing system 100 of FIG. 1. The edge ring voltage control system 200 may include a controller 202, RF generators 204, 206, match networks 208, 210, a measuring module 212, a TES ring 214 including a TES power electrode 216 and a TES probe 218, and a substrate support 220 including a RF electrode 222. The substrate support 220 supports a substrate 224 and may include a cover ring 226 and an insulator ring 228, which are similar to the rings 180, 182 of FIG. 1. An edge ring 230 is disposed on the TES ring and surrounds the substrate 224.

The TES ring 214 is disposed on the insulator ring 228 and is in contact with the edge ring 230. The TES power electrode 216 and the TES probe 218 may be embedded in the TES ring 214. The TES ring 214 and the edge ring 230 may be formed of similar materials as the rings 171, 102 of FIG. 1. Although the TES probe 218 is shown radially outward of the TES power electrode 216, the TES probe 218 may be radially inward of the TES power electrode 216. By having the TES probe radially outward, the surface area of the TES probe 218 facing the edge ring is able to be increased.

In the example shown, the TES power electrode 216 and the TES probe 218 are capacitively coupled to the edge ring 230. A cross-sectional width W1 of the TES power electrode 216 and a cross-sectional width W2 of the TES probe may be the same or different. In one embodiment, W1 is less than W2. In another embodiment, the width W1 is greater than W2. Each of the widths W1, W2, as well as other widths referred to herein, refer to differences between inner and outer diameters of electrodes and probes divided by two. The widths are determined for half cross-sections of the electrodes and probes.

In the example, shown, the TES power electrode 216 and the TES probe 218 are disposed such that there is a same gap G1 between i) TES power electrode 216 and the TES probe 218, and ii) the edge ring 230. The TES power electrode 216 and the TES probe 218 may be disposed such that the gaps between i) TES power electrode 216 and the edge ring 230, and ii) between the TES probe 218 and the edge ring 230, are different. In this example, the TES power electrode 216 and the TES probe 218 are ring-shaped.

A gap G2 exists radially between the TES power electrode 216 and the TES probe 218. The gaps G1 and G2 may be adjusted depending on i) the materials of the TES ring 214, TES power electrode 216, and TES probe 218, and ii) the voltages applied via the TES power electrode 216. The gap between the TES probe 218 and the edge ring 230 may be minimized to maximize capacitive coupling between the TES probe 218 and the edge ring 230. The gap G2 may be maximized to minimize capacitive coupling between the TES power electrode 216 and the TES probe 218. By having only the radially inner edge of the TES probe 218 facing the radially outer edge of the TES power electrode 216, the amount of surface area of the TES probe 218 facing a surface of the TES power electrode 216 is minimal. In some embodiments, the amount of capacitive coupling between the TES power electrode 216 and the TES probe 218 is negligible.

As an example, the gaps G1, G2 may be greater than or equal to 1.0 millimeters (mm). As another example, the gaps G1, G2 may be greater than or equal to 2.0 millimeters (mm). As another example, the gaps G1, G2 may each be equal to 3-5 millimeters (mm). The gaps G1, G2 may be the same or different. In one embodiment, the gap between the TES probe 218 and the edge ring 230 is less than the gap between the TES power electrode 216 and the edge ring 230. Other examples are provided below. The higher the RF voltages to be supplied to the TES power electrode 216, the larger the gap G2. The larger the gap G2, the less interference between the TES power electrode 216 and the TES probe 218.

The RF generators 204, 206 generate RF voltage signals, which are provided to the match networks 208, 210 and as a result to the RF electrode 222 and the TES power electrode 216. The match networks 208, 210 may include respective pickup sensors 240, 242, which are used to detect the RF voltages and phases of the RF signals output by the RF generators 204, 206.

The measuring module 212 may be implemented as a printed circuit board (PCB) including components for detecting RF voltage and phase via the TES probe 218. The RF voltage and phase is provided to the controller 202. The RF voltage and phase are indicative of i) the RF voltage and phase at the edge ring 230, and ii) the RF voltage and phase at an outer radially edge 250 of the substrate 224.

The controller 202 adjusts the voltages and phases output by the second RF generator 206 and thus applied to the TES probe 218 based on i) the voltages and phases of the RF signals detected by the pickup sensors 240, 242, and ii) the voltages and phases detected via the TES probe 218 and the measuring module 212. The controller 202 may control adjust the voltage of the RF signal out of the second RF generator 206 i) to match the RF voltage at the TES power electrode 216 and/or the RF voltage at the edge ring 230 with the RF voltage at the RF electrode 222, and/or ii) to adjust the RF voltage at the edge ring 230 to be within a set range of the RF voltage of the RF electrode 222. The controller 202 may adjust the RF voltage out of the RF generator 206 such that the RF voltage at the TES power electrode 216 and/or the RF voltage at the edge ring 230 is a set amount greater than or less than the RF voltage at the RF electrode 222. In an embodiment, the controller 202 is implemented as a proportional integral derivative (PID) controller.

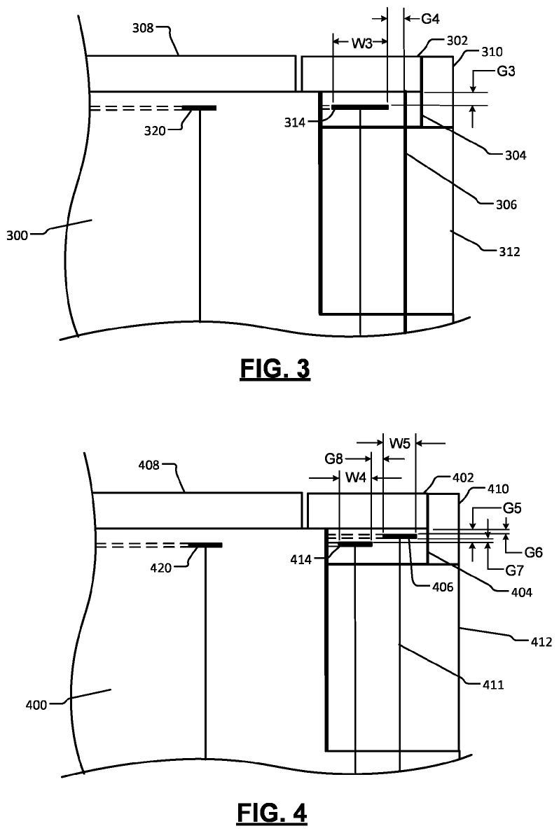

FIG. 3 shows a substrate support 300 including an edge ring 302 and an example of a TES ring 304 having a direct measurement TES probe 306. The edge ring 302 is disposed on the TES ring 304 and surrounds a substrate 308. A cover ring 310 may surround the rings 302, 304 and be disposed on an insulator ring 312. The TES probe 306 may extend vertically through the insulator ring 312 and the TES ring 304 and be in direct contact with the edge ring 302.

The TES ring 304 further includes a TES power electrode 314 that is embedded in the TES ring 304. The substrate support 300 includes a RF electrode 320. The voltages and phases of the RF signals supplied to the TES power electrode 314 and the RF electrode 320 may be controlled similarly as the voltages and phases of other TES power electrodes and RF electrodes of substrate supports referred to herein. This control may be based on the detected RF voltages and phases detected by the TES probe 306.

A gap G3 exists between the TES power electrode 314 and the edge ring 302. A gap G4 also exists radially between the TES power electrode 314 and the TES probe 306. The gaps G3 and G4 may be adjusted depending on i) the materials of the TES ring 304, TES power electrode 314, and TES probe 306, and ii) the voltages applied via the TES power electrode 314. The capacitive coupling between the TES power electrode 314 and the TES probe 306 is minimal, as the TES power electrode 314 is ring-shaped and the TES probe 306 is a conductive line arranged to detect a voltage and phase at a detection point. The TES probe 306 extends vertically through the TES ring 304. Because of this arrangement, there is minimal surface area of the TES probe 306 that faces the outer radial edge of the TES power electrode 314. The TES power electrode may have a cross-sectional width W3.

As an example, the gaps G3, G4 may be greater than or equal to 1.0 millimeters (mm). As another example, the gaps G3, G4 may be greater than or equal to 2.0 millimeters (mm). As another example, the gaps G3, G4 may be equal to 3-5 millimeters (mm). The gaps G3, G4 may be the same or different.

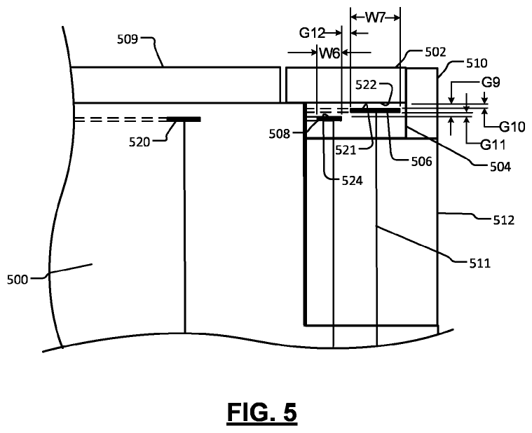

FIG. 4 shows a substrate support 400 including an edge ring 402 and an example of a TES ring 404 having an indirect measurement TES probe 406. The edge ring 402 is disposed on the TES ring 404 and surrounds a substrate 408. A cover ring 410 may surround the rings 402, 404 and be disposed on an insulator ring 412. The TES probe 406 is disposed in the TES ring 404 and is connected to a conductor 411 extending through the insulator ring 412 and into the TES ring 404.

The TES ring 404 further includes a TES power electrode 414 that is embedded in the TES ring 404 along with the TES probe 406. The TES power electrode 414 and the TES probe 406 may be ring-shaped. The substrate support 400 includes a RF electrode 420. The voltages and phases of the RF signals supplied to the TES power electrode 414 and the RF electrode 420 may be controlled similarly as the voltages and phases of other TES power electrodes and RF electrodes of substrate supports referred to herein. This control may be based on the detected RF voltages and phases detected by the TES probe 406. The TES power electrode 414 and the TES probe 406 are capacitively coupled to the edge ring 402.

A gap G5 exists between the TES power electrode 414 and the edge ring 402. A gap G6 exists between the TES probe 406 and the edge ring 402. The TES probe 406 is vertically offset from the TES power electrode 414, referred to as gap G7. A gap G8 also exists radially between the TES power electrode 414 and the TES probe 406. The gaps G5-G8 may be adjusted depending on i) the materials of the TES ring 404, TES power electrode 414, and TES probe 406, and ii) the voltages applied via the TES power electrode 414.

The capacitive coupling between the TES power electrode 414 and the TES probe 406 is minimal, as no planar surface of the TES probe 406 is facing a planar surface of the TES power electrode 414. No planar surface of the TES probe 406 is disposed directly opposite and faces a planar surface of the TES power electrode 414. This is due to: the vertical offset of the TES probe 406 relative to the TES power electrode 414: and the non-overlapping arrangement of the TES probe 406 and the TES power electrode 414 such that neither of the TES probe 406 and the TES power electrode 414 horizontally overlaps the other one of the TES probe 406 and the TES power electrode 414.

As an example, each of the gaps G5-G8 may be greater than or equal to 1.0 millimeters (mm). As another example, each of the gaps G5-G8 may be greater than or equal to 2.0 millimeters (mm). As another example, each of the gaps G5-G8 may be equal to 3-5 millimeters (mm). The gap G6 is less than the gap G5 such that there is a stronger capacitive coupling between the TES probe 406 and the edge ring 402.

The TES power electrode 414 and the TES probe 406 have cross-sectional widths W4, W5. The widths W4, W5 may be the same or different. In the example shown, the width W4 is equal to the width W5.

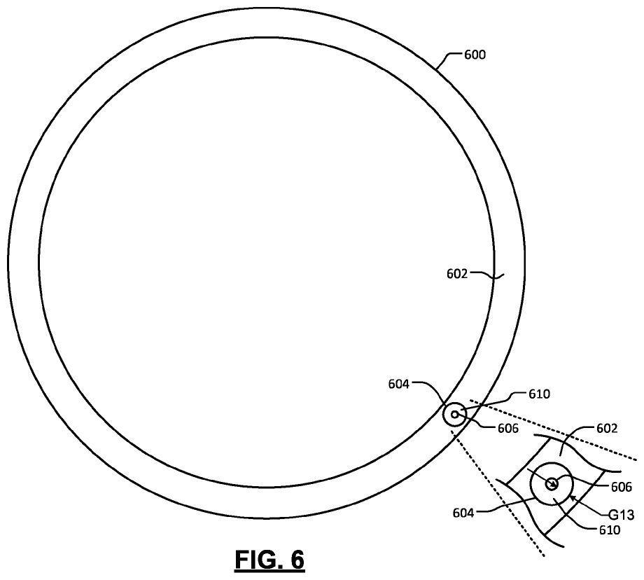

FIG. 5 shows a substrate support 500 including an edge ring 502 and an example of a TES ring 504 having an indirect measurement TES probe 506 with a larger surface area facing the edge ring 502 than does a TES power electrode 508. The edge ring 502 is disposed on the TES ring 504 and surrounds a substrate 509. A cover ring 510 may surround the rings 502, 504 and be disposed on an insulator ring 512. The TES probe 506 is disposed in the TES ring 504 and is connected to a conductor 511 extending through the insulator ring 512 and into the TES ring 504.

The TES ring 504 includes the TES power electrode 508 that is embedded in the TES ring 504 along with the TES probe 506. The TES power electrode 508 and the TES probe 506 may be ring-shaped. The substrate support 500 includes a RF electrode 520. The voltages and phases of the RF signals supplied to the TES power electrode 508 and the RF electrode 520 may be controlled similarly as the voltages and phases of other TES power electrodes and RF electrodes of substrate supports referred to herein. This control may be based on the detected RF voltages and phases detected by the TES probe 506. The TES power electrode 508 and the TES probe 506 are capacitively coupled to the edge ring 502.

A gap G9 exists between the TES power electrode 508 and the edge ring 502. A gap G10 exists between the TES probe 506 and the edge ring 502. The TES probe 506 is vertically offset from the TES power electrode 508, referred to as gap G11. A gap G12 also exists radially between the TES power electrode 508 and the TES probe 506. The gaps G5-G8 may be adjusted depending on i) the materials of the TES ring 504, TES power electrode 508, and TES probe 506, and ii) the voltages applied via the TES power electrode 508.

The capacitive coupling between the TES power electrode 508 and the TES probe 506 is minimal, as no planar surface of the TES probe 506 is facing a planar surface of the TES power electrode 508. No planar surface of the TES probe 506 is disposed directly opposite and faces a planar surface of the TES power electrode 508. This is due to: the vertical offset of the TES probe 506 relative to the TES power electrode 508: and the non-overlapping arrangement of the TES probe 506 and the TES power electrode 508 such that neither of the TES probe 506 and the TES power electrode 508 horizontally overlaps the other one of the TES probe 506 and the TES power electrode 508.

As an example, each of the gaps G9-G12 may be greater than or equal to 1.0 millimeters (mm). As another example, each of the gaps G9-G12 may be greater than or equal to 2.0 millimeters (mm). As another example, each of the gaps G9-G12 may be equal to 3-5 millimeters (mm). The gap G10 is less than the gap G9 such that there is a stronger capacitive coupling between the TES probe 506 and the edge ring 502.

The TES power electrode 508 and the TES probe 506 have cross-sectional widths W6, W7. The width W7 is greater than the width W6, such that the TES probe 506 has a larger surface area facing the edge ring 502 and thus has a greater capacitive coupling with the edge ring 502. A top planar surface 521 of the TES probe 506 faces a bottom planar surface 522 of the edge ring 502. The top planar surface 521 has a larger surface area than the surface area of a top planar surface 524 of the TES power electrode 508.

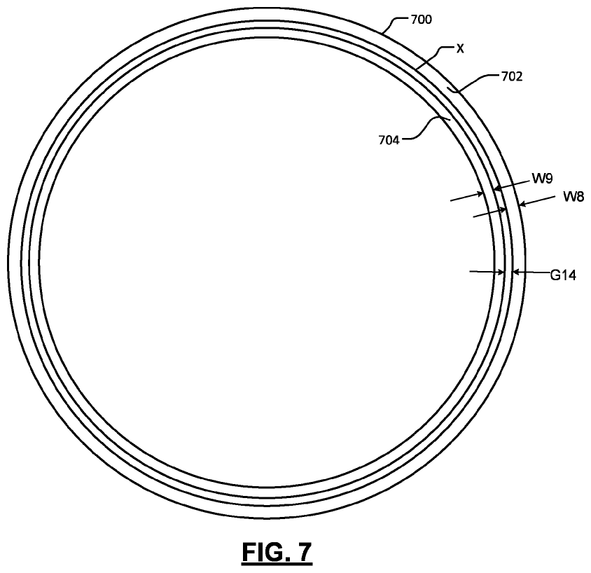

FIG. 6 shows a TES ring 600 including a ring-shaped TES power electrode 602 with an opening 604 for a direct measurement TES probe 606. A gap G13 exists between the TES power electrode 602 and the TES probe 606. A portion 610 of the body of the TES ring 600 may protrude into the opening 604 to fill the gap G13. The portion 610 may be formed of ceramic and resist current flow between the TES power electrode 602 and the TES probe 606. The portion 610 minimizes capacitive coupling between the TES power electrode 602 and the TES probe 606. The gap G13 may be greater than 1 mm. In an embodiment, the gap G13 may be greater than 2 mm. In another embodiment, the gap G13 is between 3-5 mm. The gap G13 is set based on i) the materials of the TES ring 600, TES power electrode 602, and TES probe 606, and ii) the voltages applied via the TES power electrode 602. The higher the voltages to be applied, the larger the gap G13. The TES probe 606 is configured to directly contact an edge ring. The TES power electrode 602 is configured to be capacitively coupled to the edge ring.

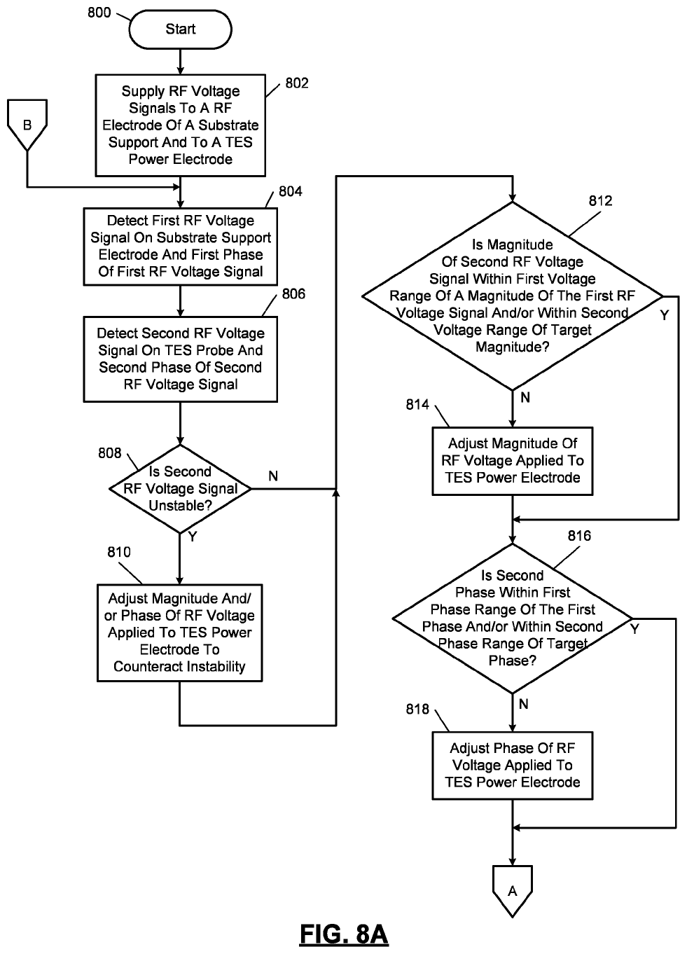

FIG. 7 shows a TES ring 700 including a ring-shaped TES power electrode 702 and a ring-shaped indirect measurement TES probe 704. The TES power electrode 702 is disposed radially outward of the TES probe 704 with a gap G14 therebetween. Although the TES probe 704 is shown disposed radially inward of the TES power electrode 702, the TES probe 704 may be disposed radially outward of the TES power electrode 702. Also, although the width W8 of the TES power electrode 702 is shown as being larger than the width W9 of the TES probe, the width W8 may be the same or less than the width W9.

The gap G14 may be greater than 1 mm. In an embodiment, the gap G14 may be greater than 2 mm. In another embodiment, the gap G14 is between 3-5 mm. The gap G14 is set based on i) the materials of the TES ring 700, TES power electrode 702, and TES probe 704, and ii) the voltages applied via the TES power electrode 702. The higher the voltages to be applied, the larger the gap G14. The TES power electrode 702 and the TES probe 704 are configured to be capacitively coupled to an edge ring.

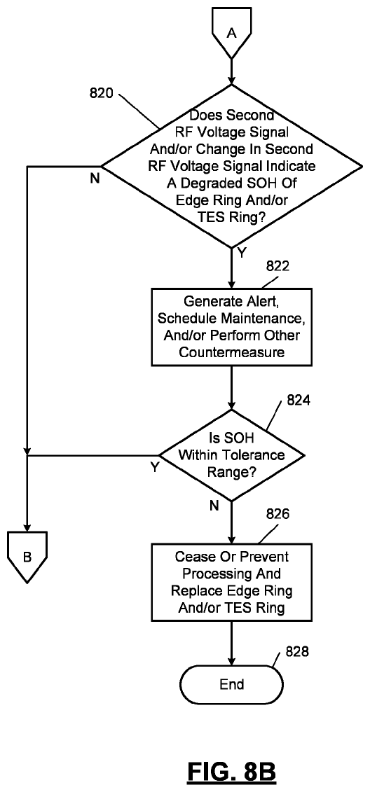

FIGS. 8A-8B shows an edge ring voltage and phase measurement and control method including diagnostic operations. The method may begin at 800 and the following operations may be performed by one of the controllers disclosed herein implementing feedback algorithms to control magnitudes and phases of an RF voltage signal at an edge ring. The operations may be iteratively performed. The provided order of operations is an example, the operations may be performed in a different order. Two or more of the operations may be performed concurrently. At 802, the controller supplies RF voltage signals via RF generators and matching networks to a RF electrode of a substrate support and to a TES power electrode (e.g., one of the TES power electrodes of FIGS. 1-7) of a TES ring.

At 804, the controller via a pickup sensor detects a first RF voltage and a first phase of a first RF signal on the RF electrode of the substrate support. At 806, the controller via the TES probe detects a second RF voltage and second phase of a second RF signal on the edge ring. The second RF voltage may be a fraction of the RF voltage applied to the TES power electrode. As an example, the voltage applied to the TES power electrode may have a magnitude of 10 kilovolts (kV) and the magnitude of the second RF voltage may be 1.5-2 kV.

At 808, the controller determines whether the second RF voltage signal is unstable. The stability of the second RF voltage signal is monitored and based on this information, the controller controls overall stability of a plasma process. The controller may track voltage fluctuations in the second RF voltage signal and when a frequency of the fluctuations is greater than a set frequency, determine the second RF voltage signal to be unstable. If unstable, then operation 810 may be performed, otherwise operation 812 may be performed.

At 810, the controller may adjust the magnitude and/or phase of the RF voltage applied to the TES power electrode to counteract the instability. For example and based on the tracked voltages of the second RF voltage signal, the controller may: estimate the magnitude and phase of the second RF voltage signal; compare the magnitude and phase to a target magnitude and phase; and based on the differences, adjust the magnitude and/or phase of the RF voltage signal applied to the TES power electrode to maintain the target magnitude and phase at the TES power electrode and/or edge ring. This may include comparing measured peak-to-peak voltages to target peak-to-peak voltages and adjusting the RF voltage applied to the TES power electrode based on differences between the measured and target peak-to-peak voltages. The target magnitude, target phase, and target peak-to-peak voltages may be the same or different than the magnitude, phase and/or peak-to-peak voltages measured via the RF electrode of the substrate support. As shown, operation 812 may be performed subsequent to operation 810. In another embodiment, operations 808-810 are performed while operations 812, 814, 816 and 818 are performed and operation 820 is performed subsequent to operation 810.

At 812, the controller may determine whether the magnitude of the second RF voltage signal is within a first voltage range of a magnitude of the first RF voltage signal and/or within a second voltage range of the target magnitude. The target magnitude may be the same or different than the magnitude of the first RF signal. If false, operation 814 is performed, otherwise operation 816 may be performed.

At 814, the controller may adjust magnitude of the RF voltage applied to the TES power electrode such that the magnitude of the second RF voltage signal is within the first voltage range of a magnitude of the first RF voltage signal and/or within the second voltage range of the target magnitude.

At 816, the controller may determine whether the phase of the second RF voltage signal is within a first phase range of a phase of the first RF voltage signal and/or within a second phase range of the target phase. The target phase may be the same or different than the phase of the first RF signal. If false, operation 818 is performed, otherwise operation 820 may be performed.

At 818, the controller may adjust phase of the RF voltage applied to the TES power electrode such that the phase of the second RF voltage signal is within the first phase range of a phase of the first RF voltage signal and/or within the second phase range of the target phase.

At 820, the controller determines whether the second RF voltage signal and/or a change in the second RF voltage signal is indicative of a degraded state of health (SOH) of the edge ring. As an example, the higher the frequency in fluctuations, and the larger the fluctuations of the second RF voltage signal, the more likely the SOH has degraded and the more the amount of degradation. The degradation may refer to degradation of the edge ring and/or TES ring. The edge ring and the TES ring may be replaceable components and when degraded to set levels, may be replaced. As another example, the lower the magnitude of the second RF voltage signal relative to the magnitude of the first RF voltage signal, the more likely the SOH has degraded and the more the amount of degradation.

Drifts in RF voltage over time due to degradation may be monitored and tracked. The SOH is directly related to the drifts in RF voltages due to degradation. This allows the controller to compensate for these drifts due to, for example, erosion of the edge ring and/or the TES ring. The compensation may include compensating for changes in plasma conditions, such as changes in impedance of plasma, due to changes in RF voltages and corresponding phases. Operation 822 may be performed if the SOH has degraded, otherwise operation 804 may be performed.

At 822, the controller may generate an alert message, schedule maintenance, and/or perform other countermeasures based on the detected degraded SOH. At 824, the controller may determine whether the SOH is within a tolerance range. If yes, operation 804 maybe performed, otherwise operation 826 may be performed and the controller may cease substrate processing and/or prevent a next processing operation to be performed until the edge ring and/or TES ring are replaced. The method may end at 828.

The above-described method may include measuring the RF voltage signal at the TES probe and creating a calibration value based on which to correlate the RF voltage signal measured at the RF electrode in the substrate support. The calibration value may refer to a RF voltage of the TES probe measured when the edge ring and TES ring are new and/or in a good SOH. The controller may generate the calibration value and based on the calibration value, a measured RF voltage signal from the RF electrode of the substrate support and a measured RF voltage signal from the TES probe, adjust a RF voltage signal supplied to the TES power electrode.

The above-described operations are meant to be illustrative examples. The operations may be performed sequentially, synchronously, simultaneously, continuously, during overlapping time periods or in a different order depending upon the application. Also, any of the operations may not be performed or skipped depending on the implementation and/or sequence of events.

The examples disclosed herein improve etch rate uniformity and ellipticity by measuring and adjusting magnitudes and phases of voltages at edge rings to match or be set based on magnitudes and phases of RF electrodes within substrate supports. The examples include direct and indirect detection of edge ring voltages and phases of the edge ring voltages, which allows for more precise control and less processing variability as target values are more easily able to be met. The examples provide indirect measurements using capacitive coupling, which minimizes and/or eliminates degradation of system operations due to metrology. The disclosed matching of magnitude, phase and/or peak-to-peak voltages at the substrate support with magnitude, phase and/or peak-to-peak voltages at an edge ring prevent distortion of plasma sheath near outer peripheral edge of a substrate on the substrate support.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from multiple fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A voltage control system comprising:
an edge ring configured to be disposed on a substrate support and surround an outer periphery of a substrate;
a tunable edge sheath (TES) ring comprising
a TES power electrode capacitively coupled to the edge ring and configured to receive a first radio frequency (RF) voltage signal, and
a TES probe electrically coupled to the edge ring and configured to detect a second RF voltage signal at the edge ring;
a generator; and
a controller configured to, based on the second RF voltage signal, control the generator to adjust the first RF voltage signal.

2. The voltage control system of claim 1, wherein the TES power electrode and the TES probe are at least partially embedded within the TES ring.

3. The voltage control system of claim 1, wherein the TES power electrode and the TES probe are fully embedded within the TES ring.

4. The voltage control system of claim 1, wherein the TES probe directly contacts the edge ring for direct detection of the second RF voltage signal.

5. The voltage control system of claim 1, wherein the TES probe is capacitively coupled to the edge ring for indirect detection of the second RF voltage signal.

6. The voltage control system of claim 1, wherein the edge ring is disposed on and is in contact with the TES ring.

7. The voltage control system of claim 1, wherein:
the TES ring has a bottom surface; and
a top surface of the TES probe faces and extends parallel to the bottom surface of the TES ring.

8. The voltage control system of claim 1, wherein at least one of the TES power electrode and the TES probe are ring-shaped.

9. The voltage control system of claim 1, wherein:
the TES power electrode is ring-shaped; and
the TES probe is disposed radially inward or radially outward of the TES power electrode.

10. The voltage control system of claim 9, wherein the TES probe extends vertically and is disposed radially outward of the TES power electrode.

11. The voltage control system of claim 1, wherein:
the TES power electrode is ring-shaped and includes an opening; and
a portion of the TES probe extends through the opening.

12. The voltage control system of claim 11, wherein a gap exists between the TES power electrode and the TES probe.

13. The voltage control system of claim 1, wherein:
the TES power electrode is ring-shaped; and
the TES probe is ring-shaped.

14. The voltage control system of claim 13, wherein a half cross-sectional width of the TES probe is greater than a half cross-sectional width of the TES power electrode.

15. The voltage control system of claim 13, wherein a half cross-sectional width of the TES probe is equal to a half cross-sectional width of the TES power electrode.

16. The voltage control system of claim 13, wherein a half cross-sectional width of the TES probe is less than a half cross-sectional width of the TES power electrode.

17. The voltage control system of claim 13, wherein the TES probe is vertically offset from the TES power electrode.

18. The voltage control system of claim 17, wherein the TES probe is disposed closer to the edge ring than the TES power electrode.

19. The voltage control system of claim 1, wherein:
the TES ring is formed of a dielectric material; and
the TES power electrode and TES probe are embedded in the TES ring such that a portion of the dielectric material is disposed between i) the TES power electrode and the TES probe, and ii) the edge ring.

20. The voltage control system of claim 1, further comprising a sensor configured to detect magnitude and phase of a third RF voltage signal supplied to a RF electrode of the substrate support,
wherein the controller is configured to, based on a magnitude and phase of the second RF voltage signal and the magnitude and phase of the third RF voltage signal, adjust the first RF voltage signal.

21. The voltage control system of claim 20, wherein the controller is configured to adjust the first RF voltage signal to match the second RF voltage signal to the third RF voltage signal in at least one of magnitude and phase.

22. The voltage control system of claim 1, wherein the controller is configured to determine whether the second RF voltage signal is unstable and compensate for the instability of the second RF voltage signal by adjusting the first RF voltage signal.

23. The voltage control system of claim 1, the controller is configured to:
based on the second RF voltage signal, determine a state of health of at least one of the edge ring or the TES ring; and
based on the state of health, determine at least one of: whether to permit continued processing of the substrate or whether to perform a countermeasure.

24. A substrate processing system comprising:
the voltage control system of claim 1;
the substrate support comprising a RF electrode; and
a sensor configured to detect a third RF voltage signal supplied to the RF electrode,
wherein the controller is configured to, based on both the second RF voltage signal and the third RF voltage signal, adjust the first RF voltage signal.
